(19) United States
(12) Patent Application Publication
(10) Pub. No.: US 2012/0251944 A1
(43) Pub. Date: Oct. 4, 2012

(54) PHOTOLITHOGRAPHY METHOD AND APPARATUS

(75) Inventors: Weifeng ZHOU, Beijing (CN); Jianshe XUE, Beijing (CN)

(73) Assignee: BOE TECHNOLOGY GROUP CO., LTD., Beijing (CN)

(21) Appl. No.: 13/433,846

(22) Filed: Mar. 29, 2012

(30) Foreign Application Priority Data
Mar. 31, 2011 (CN) 201110080114.8

(51) Int. Cl. G03F 7/075; B05C 9/00; B05C 1/02; G03F 7/004

(52) U.S. Cl. 430/270.1; 118/72; 118/73

(57) ABSTRACT

Embodiments of the disclosed technology disclose a photolithography method and apparatus, and the method comprises: hydrophobicity-treating edge portions of a surface of a substrate to be applied with photoresist; and applying hydrophilic photoresist to the surface of the substrate subject to hydrophobic treatment. With the disclosed technology, the usage amount of thinner in the edge photoresist-removing procedure can be greatly reduced or even eliminated, thereby reducing production costs and increasing production efficiency.

### BACKGROUND

Embodiments of the disclosed technology relate to a photolithography method and a photolithography apparatus.

With the rapid development of flat panel display technology in recent years, flat panel displays have made great progress in screen size and display quality. As the production scale of the flat panel display products is continuously expanding, the competition among various manufacturers is becoming more and more fierce, and the manufacturers continue to improve product performances, while also continuously strive to reduce production costs so as to improve their market competitiveness.

Photolithography process is a very critical process for the flat panel display manufacture; the process mainly comprises applying photoresist on a surface of a substrate, forming a photoresist pattern, and etching with the photoresist pattern. In order to prevent the photoresist applied on the surface of a glass substrate from dripping on a precision apparatus such as an exposure machine, it is necessary to conduct edge photoresist-removing procedure after applying photoresist on the surface of the glass substrate, i.e., using thinner to clean off the photoresist around the edges of the glass substrate surface. The composition of the thinner may be propylene glycol methyl ether acetate (PGMEA), n-butyl acetate (NBA), and a mixture thereof, etc.

The current process requires that there must be no photoresist around the edges of the glass substrate, therefore the edges of each glass substrate all have to be cleaned with thinner for several times so as to meet the requirements. However, the cleaning procedure requires using a lot of thinner, resulting in a higher production cost.

### SUMMARY

For this reason, an embodiment of the disclosed technology is to provide a photolithography method and apparatus to reduce the amount of thinner used in an edge photoresist-removing procedure and accordingly reduce production costs.

An aspect of the disclosed technology provides a photolithography method comprising: hydrophobicity-treating edge portions of a surface of a substrate to be applied with photoresist; and applying hydrophilic photoresist to the surface of the substrate subject to hydrophobic treatment.

In one example, the hydrophobic treatment of the substrate is performed with chemical including (C_{X}H_{Y})ₙSiNHSi(C_{A}H_{B})ₘ or (C_{X}H_{Y})ₙSiNSi(C_{A}H_{B})ₘSi(C_{D}H_{F})ₛ, where the values of X, A, and D are non-negative integers, the values of Y, B, and F are positive integers, and the values of m, n, and s are any integers of 1 to 3.

In another example, the (C_{X}H_{Y})ₙSiNHSi(C_{A}H_{B})ₘ is hexamethyl disilylamine (HMDS).

In another example, the (C_{X}H_{Y})ₙSiNSi(C_{A}H_{B})ₘSi(C_{D}H_{F})ₛ is nonamethyltrisilazane.

In another example, the hydrophobicity-treating edge portions of the surface of the substrate to be applied with photoresist, comprises: conveying the substrate along rollers, the rollers being in contact with the substrate at edge positions of the surface of the substrate to be applied with photoresist, and the surfaces of the rollers being applied with chemical, thereby the substrate is moved by the rotation of the rollers, the rollers apply the chemical applied on their surfaces to the substrate at the edge positions of the surface of the substrate to be applied with photoresist.

In another example, the hydrophobicity-treating edge portions of the surface of a substrate to be applied with photoresist, comprises: by way of transferring, applying chemical at the edge positions of a surface to be applied with photoresist.

In another example, the method further comprises: when only a portion of the edge positions of the surface of the substrate are subject to the hydrophobicity treatment, the edge positions of the surface of the substrate not subject to hydrophobic treatment are subject to an edge photoresist-removing treatment, after photoresist is applied to the surface of the substrate.

Another aspect the disclosed technology also provides a photolithography apparatus, comprising: a hydrophobic treatment member and a photoresist applying member. The hydrophobic treatment member is used for hydrophobicity-treating edge portions of a surface of a substrate to be applied with photoresist. The photoresist applying member is used for applying hydrophilic photoresist to the surface of the substrate subject to hydrophobic treatment.

In one example, the hydrophobic treatment member performs the hydrophobic treatment of the substrate with chemical including (C_{X}H_{Y})ₙSiNHSi(C_{A}H_{B})ₘ or (C_{X}H_{Y})ₙSiNSi(C_{A}H_{B})ₘSi(C_{D}H_{F})ₛ, where the values of X, A, and D are non-negative integers, the values of Y, B, and F are positive integers, and the values of m, n, and s are any integers of 1 to 3.

In another example, the (C_{X}H_{Y})ₙSiNHSi(C_{A}H_{B})ₘ is (CH₃)₃SiNHSi(CH₃)₃ (hexamethyl disilylamine (HMDS)).

In another example, the (C_{X}H_{Y})ₙSiNSi(C_{A}H_{B})ₘSi(C_{D}H_{F})ₛ is (CH₃)₃SiNSi(CH₃)₃Si(CH₃)₃(nonamethyltrisilazane).

In another example, the hydrophobic treatment member comprises: a chemical container, a chemical delivery member and rollers. The chemical container is used to store chemical, the chemical delivery member is, at its one end, in close contact with an outlet of the chemical container and, at the other end, in contact with a cylindrical side face of one of the rollers; the chemical container applies the chemical through the chemical delivery member onto a surface of the rollers; the rollers are in contact with the substrate at edge positions of a surface of the substrate to be applied with photoresist, and when the substrate is moved by the rotation of the rollers, the rollers apply the chemical applied on surfaces of the rollers onto the substrate at edge positions of the surface of the substrate to be applied with photoresist.

In another example, the rollers comprise two parallel rows of rollers provided above the substrate, the chemical delivery member is provided above the rollers, and the chemical container is provided above the chemical delivery member in turn.

In another example, the chemical delivery member comprises sponge or tampon.

In another example, the hydrophobic treatment member performs, by way of transferring, the hydrophobic treatment at the edge positions of the surface to be applied with photoresist.

In another example, the hydrophobic treatment member performs the hydrophobic treatment onto only partial edge positions of the surface of the substrate; correspondingly, the apparatus further comprises: an edge photoresist-removing treatment member, for removing photoresist from the edge positions of the surface of the substrate not subject to hydrophobic treatment, after the photoresist is applied to the surface of the substrate.

The photolithography method and apparatus provided in the embodiments of the disclosed technology, firstly, hydrophobicity-treat edge portions of a surface of a substrate to be applied with photoresist, and then apply hydrophilic photoresist to the surface of the substrate that has been subject to hydrophobic treatment. Since the edge positions subject to hydrophobic treatment can excellently prevent hydrophilic photoresist, when the surface of the substrate is applied with photoresist, photoresist will not remain in the edge positions subject to hydrophobic treatment. Therefore, the edge photoresist-removing procedure is eliminated for the edge positions subject to hydrophobic treatment. It can be seen, with the disclosed technology, the amount of thinner used in the edge photoresist-removing procedure can be greatly reduced or even eliminated, thereby reducing production costs of the substrate and increasing production efficiency.

Further scope of applicability of the disclosed technology will become apparent from the detailed description given hereinafter. However, it should be understood that the detailed description and specific examples, while indicating preferred embodiments of the disclosed technology, are given by way of illustration only, since various changes and modifications within the spirit and scope of the disclosed technology will become apparent to those skilled in the art from the following detailed description.

### BRIEF DESCRIPTION OF THE DRAWINGS

The disclosed technology will become more fully understood from the detailed description given hereinafter and the accompanying drawings which are given by way of illustration only, and thus are not limitative of the disclosed technology and wherein:

FIG. 1 is a flow chart of a photolithography method according to an embodiment of the disclosed technology,

FIG. 2 is a schematic structural view of a photolithography apparatus according to an embodiment of the disclosed technology,

FIG. 3 is a schematic view of a surface of a substrate subject to once HMDS application treatment in an embodiment of the disclosed technology,

FIG. 4 is a first schematic view of a surface of a substrate subject to photoresist application in the embodiment of the disclosed technology,

FIG. 5 is a second schematic view of a surface of a substrate subject to photoresist application in the embodiment of the disclosed technology, and

FIG. 6 is a schematic view of the HMDS application by way of transfer in the embodiment of the disclosed technology.

### DETAILED DESCRIPTION

Below, the embodiments of the disclosed technology will be further explained in conjunction with the accompanying drawings and specific embodiments. However, the description is not restrictive, and the scope of the disclosed technology is determined based on the accompanying claims.

In order to reduce the used amount of thinner in the edge photoresist-removing procedure and thereby reduce production costs, a photolithography method provided in an embodiment of the disclosed technology, as shown in FIG. 1, mainly comprises the following steps.

Step 101, hydrophobicity-treating edge portions of the surface of a substrate to be applied with photoresist.

In one example of the step, the substrate is subject to hydrophobic treatment with chemical; the examples of the chemical may be (C_{X}H_{Y})ₙSiNHSi(C_{A}H_{B})ₘ or (C_{X}H_{Y})ₙ SiNSi(C_{A}H_{B})ₘSi(C_{D}H_{F})ₛ, where the values of X, A, and D are non-negative integers, the values of Y, B, and F are positive integers, and the values of m, n, and s are any integers of 1 to 3.

An example of (C_{X}H_{Y})ₙSiNHSi(C_{A}H_{B})ₘ is hexamethyl disilylamine (HMDS), and an example of (C_{X}H_{Y})ₙSiNSi(C_{A}H_{B})ₘSi(C_{D}H_{F})ₛ is nonamethyltrisilazane.

Step 102, applying hydrophilic photoresist to the surface of the substrate subject to hydrophobic treatment.

After the chemical is applied at the edge positions of the surface of a substrate, photoresist is subsequently applied to the surface. This embodiment of the disclosed technology is adapted to hydrophilic photoresist. Before the chemical is applied, the hydroxyl groups in the surface of the substrate and the residual water molecules are hydrophilic, however, after the chemical is applied to the surface of the substrate at the edge positions, the chemical and the surface of the substrate undergo hydroxyl reaction, forming silyl ether (at the edge positions) in the surface of the substrate and eliminating the hydrogen-bonding (at the edge positions) of the surface, thereby making the edge positions of the surface change from hydrophilic to hydrophobic (that is, the edge positions change from a polar surface to a non-polar surface). Since the hydrophobic groups at the edge positions can excellently block hydrophilic photoresist, they can function as a blocker.

It can be seen that, since the edge positions subject to the hydrophobic treatment can excellently prevent hydrophilic photoresist, when the surface of a substrate is applied with hydrophilic photoresist, the hydrophilic photoresist will not remain at the edge positions subject to hydrophobic treatment, thus the edge photoresist-removing procedure can be eliminated for the edge positions subject to hydrophobic treatment, thereby can greatly reducing or even eliminating the usage amount of thinner in the edge photoresist-removing procedure.

Corresponding to the photolithography method described above, the photolithography apparatus provided in an embodiment of the disclosed technology at least comprises: a hydrophobic treatment member and a photoresist applying member. The hydrophobic treatment member is used for hydrophobicity-treating the edge portions of the surface of a substrate to be applied with photoresist, and the photoresist applying member is used for applying hydrophilic photoresist to the surface of the substrate subject to hydrophobic treatment.

Moreover, hydrophobic treatment member not only can be used for hydrophobicity-treating all edge positions of the surface to be applied with photoresist, but also can be used for hydrophobicity-treating only a portion of the edge positions of a surface to be applied with photoresist. If hydrophobic treatment is implemented only at a portion of the edge positions of a surface to be applied with photoresist, the apparatus can further comprise: an edge photoresist-removing treatment member, for the edge photoresist-removing treatment on the edge positions of the surface of the substrate not subject to hydrophobic treatment, after photoresist is applied to the surface of the substrate.

Below, with HMDS chemical as an example, the embodiments of the photolithography method and apparatus according to the disclosed technology will be further explained.

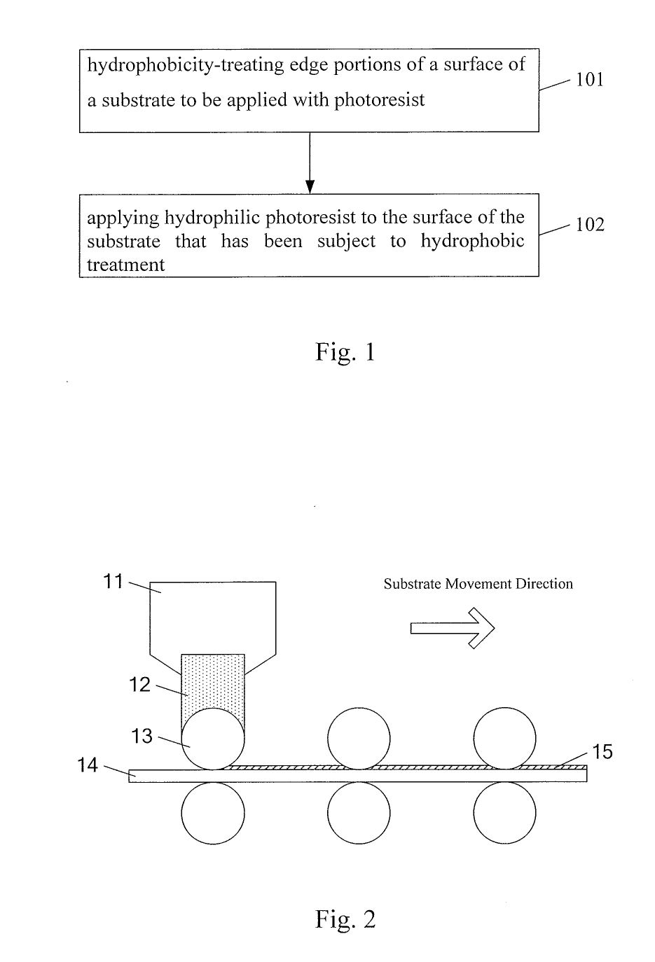

FIG. 2 is a schematic structural view of a photolithography apparatus provided in an embodiment of the disclosed technology. As shown, the apparatus mainly comprises: a chemical container 11, a chemical delivery member 12, and rollers 13. The chemical delivery member 12 may be implemented as a member comprising sponge or tampon or the like which can adsorb chemical, and the chemical includes a component of (C_{X}H_{Y})ₙ SiNHSi(C_{A}H_{B})ₘ or (C_{X}H_{Y})ₙSiNSi(C_{A}H_{B})ₘSi(C_{D}H_{F})ₛ; HMDS is an example of the chemical.

The chemical container 11 is used to store chemical, for example, HMDS chemical;

The chemical delivery member 12 is, at its one end, in close contact with an outlet of the chemical container 11 and, at the other end, in contact with a cylindrical side face of one of the rollers 13. The chemical container 11 applies the chemical through the chemical delivery member 12 to a surface of the rollers 13.

The rollers 13 comprise two rows of parallel rollers 13 provided above the substrate 14, the chemical delivery member 12 is provided above the rollers 13, and the chemical container 11 is provided above the chemical delivery member 12 in turn.

The rollers 13 are in contact with the substrate 14 at edge positions of the surface of the substrate 14 to be applied with photoresist, and when the substrate 14 are moved by the rotation of the rollers, applying (transferring) the HMDS chemical applied on the surfaces of the rollers to the substrate 14 at edge positions of the surface thereof to be applied with photoresist. On the substrate 14, the part applied with HMDS chemical is shown as a shaded part indicated by the reference number 15 in FIG. 2.

It should be noted that, FIG. 2 only illustrates a schematic sectional view of the photolithography apparatus. In implement, since the rotation of the rollers 13 brings the substrate 14 into movement, rollers 13 are usually provided at both edge positions corresponding to both sides of the substrate 14. That is, there is also provided another row of rollers 13 at the right back of the rollers 13 as shown in FIG. 2, so that these two rows of parallel rollers 13 can rotate and thus move the substrate 14. The locations of these two rows of rollers 13 are exactly corresponding to the two edge positions parallel to each other on the surface of the substrate 14. When these two rows of rollers 13 rotate, the substrate 14 is conveyed accordingly, and the chemical delivery member 12 applies HMDS chemical to the cylindrical surfaces of the rollers 13, which in turn apply (transfer) the HMDS chemical onto the two edge positions parallel to each other on the surface of the substrate 14.

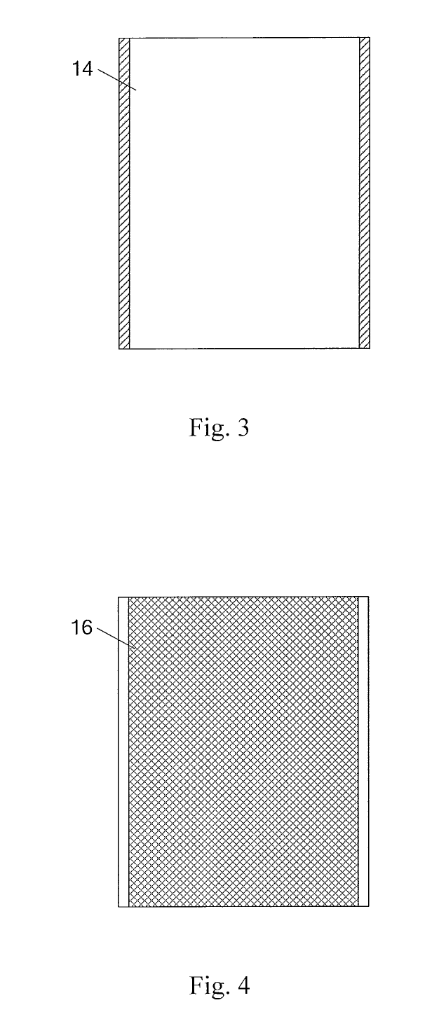

FIG. 3 shows a schematic view of a surface of the substrate 14 subject to once HMDS chemical application treatment. It can be seen, the two edge positions parallel to each other on the surface of the substrate 14 have been applied with HMDS (shown as the shaded part in the drawing), and the parallel edge positions are exactly the locations in contact with the two rows of rollers 13 in a conveying procedure.

After a surface of the substrate 14 is subject to HMDS application treatment, the surface that has been subject to the hydrophobic treatment can be further subject to a photolithography process treatment which applies photoresist on the surface. The photolithography process treatment can be performed by a dedicate member (not shown in FIG. 2) for photolithography process treatment. FIG. 4 shows a schematic view of the surface of the substrate 14 subject to the photolithography process treatment, in which the shaded part indicated by the reference number 16 represents the portion covered with photoresist on the surface of the substrate 14.

The embodiments of the disclosed technology are adapted to hydrophilic photoresist. Before HMDS is applied, the hydroxyl groups in the surface of the substrate 14 and the residual water molecules are hydrophilic; however, after HMDS is applied to the surface of the substrate 14 at the edge positions (as the shaded part shown in FIG. 3), HMDS and the surface of the substrate 14 conduct hydroxyl reaction, forming silyl ether in the surface of the substrate 14 (forming silyl ether at the shaded part as shown in FIG. 3), and eliminating hydrogen-bonding, thereby making the edge positions of the surface change from hydrophilic to hydrophobic (that is, the edge positions change from a polar surface to a non-polar surface). Since the hydrophobic groups on the edge positions can excellently prevent hydrophilic photoresist, they can function as a blocker.

Next, since the edge positions subject to HMDS treatment can excellently prevent photoresist, when the surface of the substrate 14 is applied with photoresist, the photoresist will not remain at the edge portions while passing through the edge positions subject to HMDS treatment (as the blank positions shown in FIG. 4, there is no remains on the blank positions), thereby the edge photoresist-removing procedure is eliminated for the edge positions subject to HMDS treatment, thereby the usage amount of thinner in the edge photoresist-removing procedure can be greatly reduced or even eliminated.

Additionally, it should be noted that, according to the structure as shown in FIG. 2, usually one substrate 14 has to be subject to twice HMDS application treatments, so as to apply HMDS onto all the peripheral four edge positions of the surface. The substrate 14 shown in FIG. 3 is a result of only once HMDS application treatment, that is, HMDS is applied at the edge positions only on the left and right sides in the surface of the substrate 14, but not applied at the edge positions on the up and down sides. If there is necessary to perform a second HMDS application treatment, the edge positions on the up and down sides of the surface of the substrate 14 as shown in FIG. 3 are rotated to be respectively in contact with rollers 13 and then pass by the rollers 13 once again.

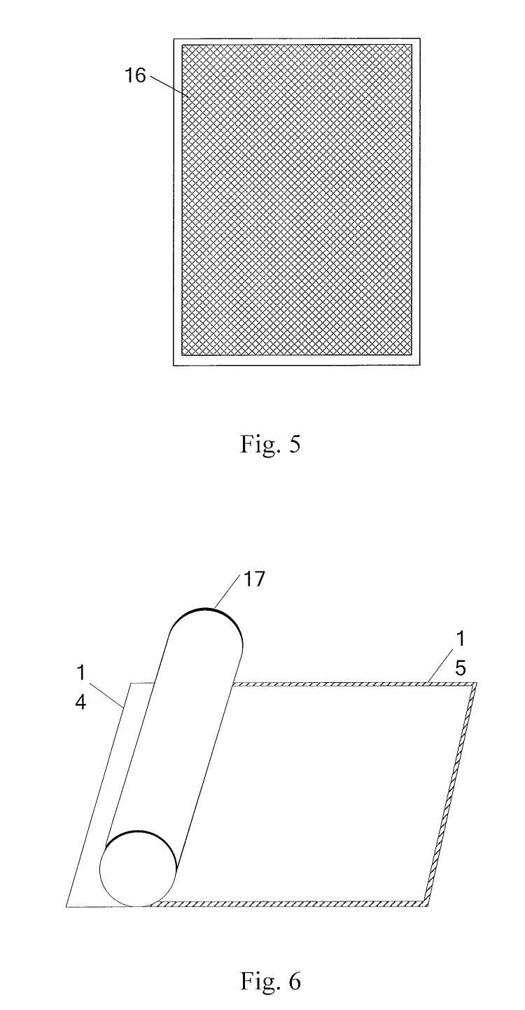

After twice HMDS application treatments, HMDS is applied all around the surface of the substrate 14, then the surface is supplied for the subsequent photolithography process treatment, after which the resultant surface of the substrate 14 is shown in FIG. 5, that is, the peripheral four edge positions of the surface of the substrate 14 are exposed through the applied photoresist, whereas the position covered with photoresist is shown as the shaded part indicated by the reference number 16 in FIG. 5.

After the substrate 14 is subject to twice HMDS application treatments as described above, since the peripheral four edge positions in a surface of the substrate 14 are completely not covered with photoresist, there is no need to conduct edge photoresist-removing treatment to the edge positions, thereby the usage amount of thinner in an edge photoresist-removing procedure can be reduced or even eliminated, reducing production costs, and increasing production efficiency.

If the substrate 14 is subject to only once HMDS application treatment as described above, the surface subject to photolithography process treatment is as shown in FIG. 4. Since the edge positions on the up and down sides of the surface of the substrate 14 are covered with photoresist, there is necessary to conduct the edge photoresist-removing treatment to the edge positions on the up and down sides, in which thinner is used to clean off or remove photoresist at the edge positions on the up and down sides, and the effect of the edge photoresist-removing treatment is the same as shown in FIG. 5. Even in this case, since there are only the edge positions on the up and down sides, for example, needed to be subject to an edge photoresist-removing treatment, compared with the case in prior art in which the peripheral four edge positions of a surface of the substrate 14 are all subject to an edge photoresist-removing treatment, this embodiment of the disclosed technology also can save or even eliminated the amount of thinner in an edge photoresist-removing procedure, reducing production costs.

In another embodiment of the disclosed technology, HMDS chemical may be applied by way of transferring to edge positions of the surface to be subject to photolithography process treatment. Specifically, as shown in FIG. 6, an APR (Asahikasei Photosensitive Resin, which is a photosensitive resin developed by Asahi Kasei Corporation, Japan) plate 17 having the same area as the substrate 14 is used. The APR plate 17 has protrusions at peripheral four edges of its surface, and the protrusions are applied with HMDS chemical. The APR plate 17 is wrapped around the rollers, with the protrusions at the edge positions on the up and down sides of the APR plate 17 shown as the black filled part in FIG. 6, and the protrusions at the edge positions on the left and right sides of the APR plate 17 are not shown in FIG. 6. The width of the protrusions is corresponding to the width of the edge positions s of the substrate 14 shown as 15 in the drawing. When the rollers 13 are rolled on the substrate 14, the HMDS on the protrusions of the APR plate 17 is applied to the substrate 14 at edge positions (as the shaded part shown in the figure) by way of transferring, thus with one rotation on the substrate 14, the rollers 13 can apply HMDS to all the peripheral four edges of the substrate 14.

The embodiment of the disclosed technology being thus described, it will be obvious that the same may be varied in many ways. Such variations are not to be regarded as a departure from the spirit and scope of the disclosed technology, and all such modifications as would be obvious to those skilled in the art are intended to be included within the scope of the following claims.

1. A photolithography method comprising:
hydrophobicity-treating edge portions of a surface of a substrate to be applied with photoresist; and
applying hydrophilic photoresist to the surface of the substrate that has been subject to hydrophobic treatment.

2. The photolithography method according to claim 1, wherein the hydrophobic treatment of the substrate is performed with chemical including (C_{X}H_{Y})ₙSiNHSi(C_{A}H_{B})ₘ or (C_{X}H_{Y})ₙSiNSi(C_{A}H_{B})ₘSi(C_{D}H_{F})ₛ, where the values of X, A, and D are non-negative integers, the values of Y, B, and F are positive integers, and the values of m, n, and s are any integers of 1 to 3.

3. The photolithography method according to claim 2, wherein the (C_{X}H_{Y})ₙSiNHSi(C_{A}H_{B})ₘ is hexamethyl disilylamine (HMDS).

4. The photolithography method according to claim 2, wherein the (C_{X}H_{y})ₙSiNSi(C_{A}H_{B})ₘSi(C_{D}H_{F})ₛ is nonamethyltrisilazane.

5. The photolithography method according to claim 1, wherein the hydrophobicity-treating edge portions of the surface of the substrate to be applied with photoresist comprises:
conveying the substrate along rollers, the rollers being in contact with the substrate at edge positions of the surface of the substrate to be applied with photoresist, and the surfaces of the rollers being applied with chemical, thereby the substrate is moved by the rotation of the rollers, the rollers apply the chemical applied on their surfaces to the substrate at the edge positions of the surface of the substrate to be applied with photoresist.

6. The photolithography method according to claim 1, wherein the hydrophobicity-treating edge portions of the surface of a substrate to be applied with photoresist comprises:
by way of transferring, applying chemical at the edge positions of the surface to be applied with photoresist.

7. The photolithography method according to claim 1, further comprising:
when only a portion of the edge positions of the surface of the substrate are subject to the hydrophobicity treatment, the edge positions of the surface of the substrate not subject to hydrophobic treatment are subject to an edge photoresist-removing treatment, after photoresist is applied to the surface of the substrate.

8. A photolithography apparatus comprising:
a hydrophobic treatment member, and
a photoresist applying member,
wherein the hydrophobic treatment member is used for hydrophobicity-treating edge portions of a surface of a substrate to be applied with photoresist; and
the photoresist applying member is used for applying hydrophilic photoresist to the surface of the substrate that has been subject to hydrophobic treatment.

9. The photolithography apparatus according to claim 8, wherein the hydrophobic treatment member performs the hydrophobic treatment of the substrate with chemical including (C_{X}H_{Y})ₙSiNHSi(C_{A}H_{B})ₘ or (C_{X}H_{Y})ₙ SiNSi(C_{A}H_{B})ₘSi(C_{D}H_{F})ₛ, where the values of X, A, and D are non-negative integers, the values of Y, B, and F are positive integers, and the values of m, n, and s are any integers of 1 to 3.

10. The photolithography apparatus according to claim 9, wherein the (C_{X}H_{Y})ₙSiNHSi(C_{A}H_{B})ₘ is hexamethyl disilylamine (HMDS).

11. The photolithography apparatus according to claim 9, wherein the (C_{X}H_{Y})ₙSiNSi(C_{A}H_{B})ₘSi(C_{D}H_{F})ₛ is nonamethyltrisilazane.

12. The photolithography apparatus according to claim 8, wherein the hydrophobic treatment member comprises:
a chemical container,
a chemical delivery member, and
rollers,
wherein the chemical container is used to store chemical,
the chemical delivery member is, at its one end, in close contact with an outlet of the chemical container and, at the other end, in contact with a cylindrical side face of one of the rollers;
the chemical container applies the chemical through the chemical delivery member onto a surface of the rollers; and
the rollers are in contact with the substrate at edge positions of a surface of the substrate to be applied with photoresist, and when the substrate is moved by the rotation of the rollers, the rollers apply the chemical applied on surfaces of the rollers onto the substrate at edge positions of the surface of the substrate to be applied with photoresist.

13. The photolithography apparatus according to claim 12, wherein the rollers comprise two parallel rows of rollers provided above the substrate, the chemical delivery member is provided above the rollers, and the chemical container is provided above the chemical delivery member in turn.

14. The photolithography apparatus according to claim 12, wherein the chemical delivery member comprises sponge or tampon.

15. The photolithography apparatus according to claim 8, wherein the hydrophobic treatment member performs, by way of transferring, the hydrophobic treatment at the edge positions of the surface to be applied with photoresist.

16. The photolithography apparatus according to claim 8, wherein the hydrophobic treatment member performs the hydrophobic treatment onto only partial edge positions of the surface of the substrate;
correspondingly, the apparatus further comprises: an edge photoresist-removing treatment member, for removing photoresist from the edge positions of the surface of the substrate not subject to hydrophobic treatment, after the photoresist is applied to the surface of the substrate.
